(19) United States
(12) Patent Application Publication
(10) Pub. No.: US 2010/0052177 A1
(43) Pub. Date: Mar. 4, 2010

(54) METHOD FOR MANUFACTURING A CROSSBAR CIRCUIT DEVICE

(75) Inventor: Peter Bartus Leonard Meijer, Eindhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 11/916,122

(22) PCT Filed: May 24, 2006
(86) PCT No.: PCT/IB2006/051660

§ 371 Date: Nov. 23, 2009

(30) Foreign Application Priority Data
Jun. 6, 2005 (EP) 05104901.3

(51) Int. Cl. H01L 23/52; B05D 5/12; H05K 1/11; B29C 59/00; H01L 21/768

(52) U.S. Cl. 257/773; 427/97.1; 174/261; 425/470; 438/622; 257/E21.575; 257/E23.141

(57) ABSTRACT

Method for manufacturing a crossbar circuit on a substrate (1), the crossbar circuit comprising a first grid of first wires (10) and a second grid of second wires (17), the first wires extending in a first direction, the second wires extending in a second direction, the first direction and the second direction being arranged relative to each other to form a single two-dimensional wire grid, each first wire being separated from each second wire by an intermediate layer (14) located at a location where the first and second wires overlap; the method comprising: depositing an unprintable layer (2) on the substrate, imprinting a two-dimensional grid mask (5) into the unprintable layer by a mould (3); directionally depositing a first material (8) in the first direction on the grid mask; and directionally depositing a second material (15) in the second direction on the grid mask, the grid mask acting as a shadow mask during the directional deposition of the first and second material.

### FIELD OF THE INVENTION

The present invention relates to a method for manufacturing a crossbar circuit device, as defined in the preamble of claim 1. Also, the present invention relates to a crossbar circuit device.

### PRIOR ART

Crossbar circuits are for example known from U.S. Pat. No. 6,128,214.

A crossbar circuit (or crossbar network) typically consists of two perpendicularly oriented 1-D conductive wire grids with devices such as a fuse, a programmable resistor or a transistor at the intersections between a wire in one grid and a wire in the other grid, which with respect to each other run perpendicularly in different layers, and is considered as a structure for future nano-scale circuits. Such structures are highly tolerant to misalignment, and hence relatively easy and cheap to manufacture.

To create a crossbar circuit, a technology known as nano-imprint lithography can be used, which applies imprinting each of the respective wire grids in a resist layer by means of a mould or stamp.

One of the main foreseen bottlenecks in nano-imprint lithography is a limitation of production throughput. This is mainly due to the flow time of the resist underneath the stamp, plus the time needed to harden the resist, for instance via ultraviolet (UV) curing as is used in the S-FIL (step and fill imprint lithography) process.

With nano-imprint lithography, one envisions at least two lithographic steps, i.e., a first step for the first 1-D (one dimensional) wire grid, and subsequently a second step for the second wire grid, which is rotated through 90° with respect the first grid. The imprinting process has to be applied at least twice to define the bottom and the top interconnect layer separately in a 2-layer interconnect structure. One firsts creates the bottom 1-D interconnect grid layer, then the device/memory layer, and finally the top 1-D interconnect grid layer.

In addition, nano-imprint lithography applies techniques such as resist lift-off, etching and planarisation before adding the next interconnect layer. Consequently, there is a need to have multiple moves in and out of vacuum for the various steps, with possible contamination in (or between) any of these steps.

Moreover, the steps of lift-off, etching and planarisation add considerably to the time needed to create a crossbar circuit.

### SUMMARY OF THE INVENTION

It is desirable to reduce the number of processing steps for making a crossbar circuit and consequently to reduce the processing time.

According to an aspect of the invention, there is a method for manufacturing a crossbar circuit device on a substrate, the crossbar circuit device comprising a first grid of first wires and a second grid of second wires, the first wires extending in a first direction, the second wires extending in a second direction, the first direction of the first wires and the second direction of the second wires being arranged relative to each other for forming a two-dimensional wire grid, each first wire being separated from each second wire by an intermediate layer located at a location where the first wire and the second wire overlap; the method comprising a step of depositing an imprintable layer on the substrate, characterized by
imprinting a two-dimensional grid mask into the imprintable layer by a mould, the grid mask comprising a plurality of poles and openings interposed between adjacent poles and said grid mask being complementary to the two-dimensional wire grid;
directionally depositing a first material in substantially the first direction on the two-dimensional grid mask; and
directionally depositing a second material in substantially the second direction on the two-dimensional grid mask, the two-dimensional grid mask acting as a shadow mask during the directional deposition of the first and second material.

Advantageously, the present invention achieves that a single grid mask can be used for both the first and the second wire grid. Consequently, the processing is simplified and the relatively long time needed to define separate wire grids for the first wires and the second wires is reduced by at least 50%.

According to a further aspect of the invention, there is a crossbar circuit device comprising a first grid of first wires and a second grid of second wires, the first wires extending in a first direction, the second wires extending in a second direction, the first direction of the first wires and the second direction of the second wires being arranged relative to each other to form a single two-dimensional wire grid, each first wire being separated from each second wire by an intermediate layer located at a location where the first wire and the second wire overlap;

the crossbar circuit device being manufactured in accordance with the method described above.

According to yet another aspect of the invention, there is a mould for use in the method described above, the mould comprising on its surface a geometrical shape for imprinting, characterized in that the geometrical shape comprises a two-dimensional grid mask.

According to another aspect of the invention, there is a method for manufacturing a semi-conductor device comprising the method for manufacturing a crossbar circuit device as described above.

According to still another aspect of the invention, there is a semi-conductor device comprising a crossbar circuit device as described above.

### BRIEF DESCRIPTION OF DRAWINGS

The invention will be explained in more detail below with reference to a few drawings in which illustrative embodiments thereof are shown. They are intended exclusively for illustrative purposes and do not restrict the inventive concept, which is defined by the claims.

FIGS. 1a-1e illustrate the formation of a crossbar resist mask;

FIG. 2 shows a top view of an exemplary crossbar resist mask;

FIG. 3 shows a perspective view of the crossbar resist mask on the substrate;

FIG. 4 shows a first cross-sectional view of the crossbar resist mask after a first deposition step;

FIG. 5 shows a second cross-sectional view of the crossbar resist mask after a first deposition step;

FIG. 6 shows a plane view of the crossbar resist mask after the first deposition step;

FIG. 7 shows the first cross-sectional view of the crossbar resist mask after a second deposition step;

FIG. 8 shows the second cross-sectional view of the crossbar resist mask after a third deposition step;

FIG. 9 shows the first cross-sectional view of the crossbar resist mask after the third deposition step;

FIG. 10 shows a cross-sectional view of the deposited structure after lift-off along a line X-X;

FIG. 11 shows a further cross-sectional view of the deposited structure after lift-off along line XI-XI;

FIG. 12 shows a schematic layout of a crossbar circuit and part of a peripheral circuit before removal of the resist layer;

FIG. 13 shows a schematic layout of an adapted crossbar circuit and part of a peripheral circuit before removal of the resist layer, and

FIG. 14a-14d illustrate the formation of a crossbar resist mask according to a further embodiment of the present invention.

### DESCRIPTION OF PREFERRED EMBODIMENTS

In this application, it is proposed to use only a single lithographic step, e.g., via nano-imprint, for manufacturing a two-layer crossbar network, e.g., for manufacturing very high density memories.

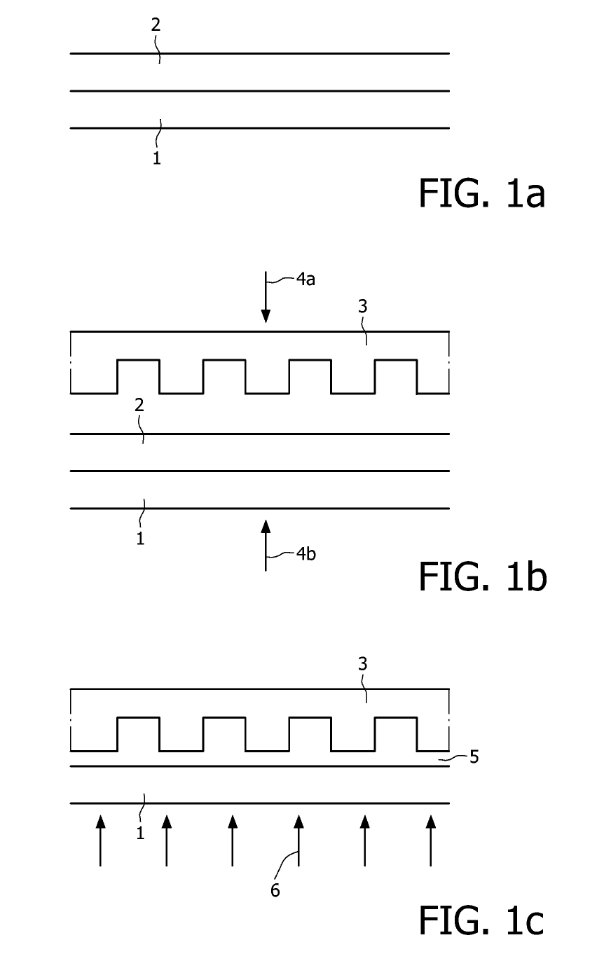

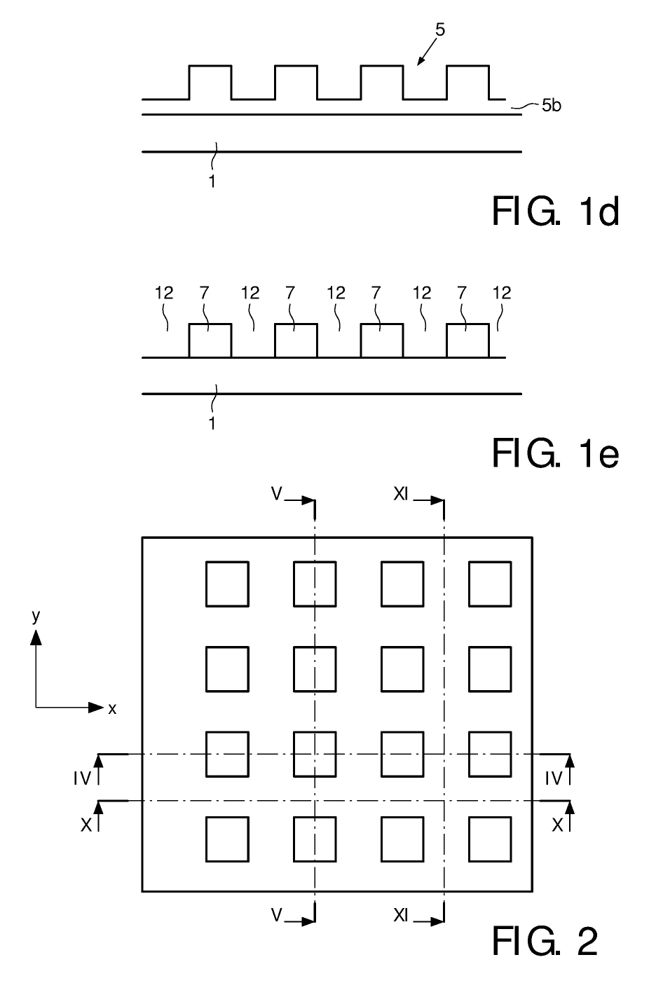

FIGS. 1a-1e illustrate the formation of a crossbar resist mask M. The crossbar resist mask is manufactured as follows:

On a substrate 1 an imprintable resist layer 2 is deposited, for example by spin coating (FIG. 1a) or a ‘drop-on-demand’ process. The substrate 1 typically comprises an isolator layer and may be transparent to radiation if the resist is cured by radiation (e.g. UV) in a later step. The resist layer 2 may have a thickness from about 3 to about 30 nm and may comprise any suitable resist material.

Next in FIG. 1b, a mould or stamp 3, which comprises a geometrical shape to be imprinted in the resist layer 2, is brought into contact with the resist layer 2.

The geometrical shape on the print surface of the mould 3 comprises a 2-D (two dimensional) orthogonal wire grid that is the merger of the first and second 1-D wire grids at perpendicular orientations. Instead of imprinting a first 1-D wire grid and subsequently a second 1-D wire grid at a perpendicular orientation relative to the first 1-D wire grid, the 2-D orthogonal wire grid is imprinted in one single step. This 2-D wire grid thus leaves a crossbar resist mask comprising a regular array of square or rectangular raised “poles” after imprint. Please note that the present invention is not limited to an orthogonal 2D grid layout. As will be appreciated by persons skilled in the art, the present invention can be applied in other 2D grid geometries (hexagonal, triangular, etc.) as well.

The mould or stamp 3 for the 2-D grid may be obtained via direct e-beam writing or via bottom-up growth or any other suitable technique, as with known nano-imprint techniques. The mould now simply has a pattern, which is identical to the desired shape of the 2-D wire grid. The mould 3 imprints the 2-D wire grid into the resist layer 2, which after hardening holds a 2-D grid mask 5, which is complementary to the 2-D wire grid to be formed (thus: a line in the grid mask becomes a trench in the wired grid and a trench in the grid mask becomes a line in the wired grid).

FIG. 1c shows a curing step of the resist layer. The resist layer is hardened into a shaped resist mask by means of UV radiation 6, which comprises the 2-D grid mask 5.

FIG. 1d shows the 2-D grid mask portion 5 of the shaped resist mask after removal of the mould 3. As shown here, after curing/hardening the resist mask may comprise a thin residue layer portion 5b in the recessed areas of the actual 2-D grid mask 5. Such a thin residue layer portion 5b is typically thinner than the resist layer 5 as deposited, say 10% or less. The actual thickness of the residue portion 5b may vary depending on the resist material as used, the pressure exerted on the resist layer during imprinting, and the imprinting time.

The residue layer 5b may be removed by etching (as shown in FIG. 1e) to obtain openings 12 (i.e., open surface of the substrate 1) between the now free-standing resist poles 7 of the crossbar resist mask M.

It is noted that an aspect ratio of the crossbar resist mask to be formed, i.e., the ratio of the height of the poles 7 and the width of the openings 12 between (directly) adjacent poles 7, from about 1 to about 2 will be sufficient in most cases to carry out the method according to the present invention. The poles 7 may have a height substantially equal to the thickness of the resist layer 2, say 10 nm. For the given aspect ratio range, the width of the openings 12 between poles 7 is preferably between about 5 and about 10 nm in this example.

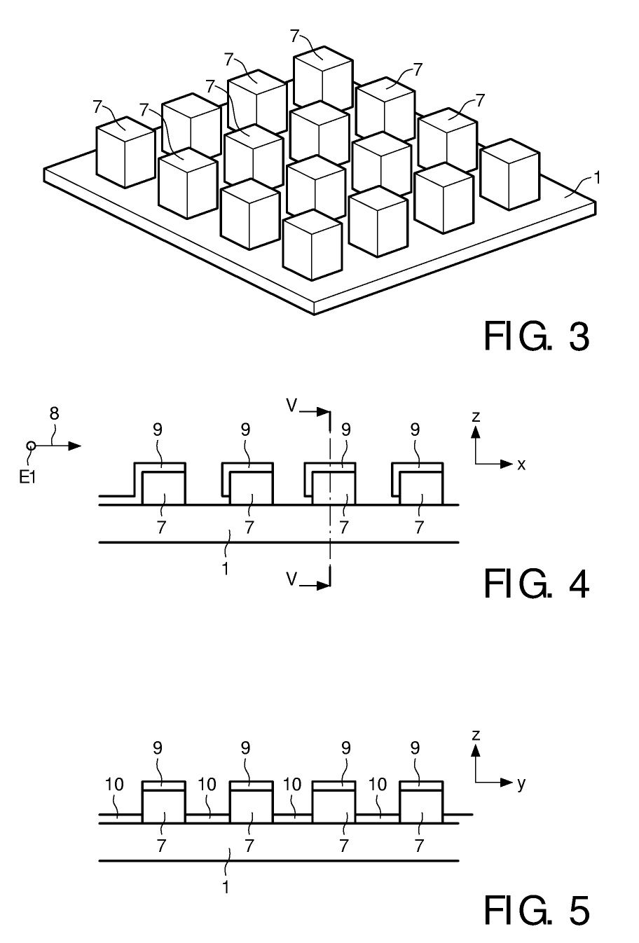

FIG. 2 shows a top view of the crossbar resist mask M. Clearly, the order of the free standing poles 7 defines an orthogonal 2-D grid on the substrate surface between them. The orthogonal directions X and Y are shown for reference. Line IV-IV indicates the cross-sectional line of the first cross-sectional view as shown in FIG. 4. Line V-V indicates the cross-sectional line of the second cross-sectional view as shown in FIG. 5. Lines X-X and XI-XI will be discussed below with reference to FIG. 10 and FIG. 11, respectively.

FIG. 3 shows a perspective view of the crossbar resist mask M on the substrate 1. Poles 7 are represented by rectangular blocks. Reference numbers to some blocks have been omitted for reasons of clarity. The poles 7 are arranged on the substrate 1 in such a way that the mask is defined for the creation of a crossbar circuit.

FIG. 4 shows a first cross-sectional view of the crossbar resist mask M after a first deposition step. The cross-sectional view extends in direction X along line IV-IV of FIG. 2.

In a vacuum, a first deposition source E1 produces a first metal 8 (or other conductive material). The metal vapour is directed towards the substrate 1 under a suitable angle (as shown by arrow 8) with the normal direction of the imprinted substrate 1, and otherwise in or along the direction X of one of the wire sets to be formed in the 2-D grid.

Assuming line-of-sight shadowing, the deposition angle to the normal direction of the imprinted substrate depends on the aspect ratio of the height of resist layer and the width of the openings 12 in the grid mask 5. For example, at an aspect ratio between 0.5 and 2 the deposition angle is for instance between about 60 and about 45 degrees relative to the substrate's normal direction. As will be appreciated by the person skilled in the art, a higher aspect ratio will allow a smaller deposition angle with respect to the normal direction.

The first metal 8 produced by the first source E1 is deposited on the surface of the substrate 1, if the poles 7 do not provide a shadow mask. In the direction X the resist mask poles 7 are covered by a metal layer 9 on their top area and on their respective side that faces the first deposition source E1. Portions of the openings 12 of the substrate in the crossbar resist mask M that are shadowed by the poles 7 remain free of metal.

The first metal 8 produced by the first source E1 reaches the bottom of the imprinted openings 12 only with the lines that run in the selected deposition direction, which is parallel to direction X, making lower conductive wires 10 (e.g., along line IX-IX), while the wires running in the perpendicular direction Y are implicitly “cut” by the “shadow” of the raised resist poles 7.

Note that both the aspect ratio of the openings 12 between the poles 7 and the deposition angle are chosen in such a way that deposited first metal 8 only reaches the top and part of the facing sides of the raised poles and not the openings 12 between the poles 7 insofar as these openings 12 are shadowed by the poles 7 relative to the first source E1.

The thickness of the metal layer 9 is preferably less than about half of the resist layer thickness. A lower limit is presented by the requirement that the conductive wires are (at least) electrically conductive. The actual minimal thickness may depend on the species of the first metal 8 and its properties, for example the nucleation of the metal on the surface and the wetting of the surface.

It is noted that the metal flow 8 from the source E1 may be produced by evaporation, directional sputtering or by a molecular beam.

The deposition of the first metal 8 may be preceded by a deposition of a relatively thin adhesion layer on the surface of the substrate 1, which enhances the adhesion of the first metal on that surface. Also, the adhesion layer may function as a seed layer, depending on the deposition method used for the first metal. The adhesion layer is typically about a few atomic layers thick.

FIG. 5 shows a second cross-sectional view of the crossbar resist mask M after a first deposition step. The cross-sectional view extends in direction Y along line V-V of FIG. 2. The metal layer 9 is deposited on top of the resist poles 7. Lower conductive wires 10 extending in the X direction have been deposited on the substrate 1 between the poles 7.

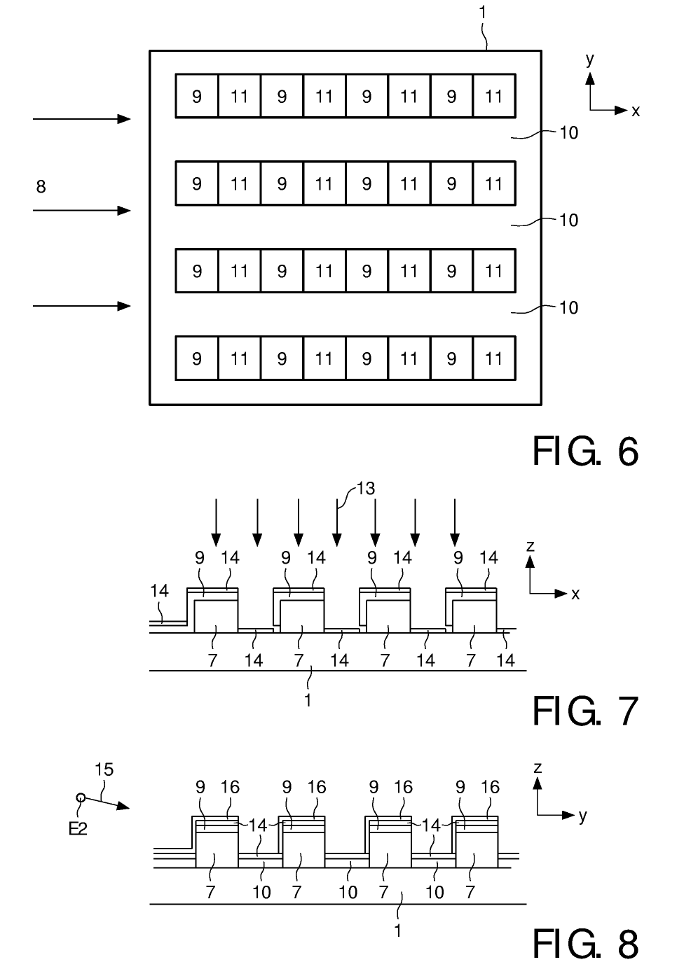

FIG. 6 shows a plane view of the crossbar resist mask after the first deposition step. In FIG. 6 entities with the same reference number refer to identical entities as shown in the preceding figures. The poles 7 of resist mask pattern M are covered by metal 9 on substrate 1. The lower conductive wires 10 extend between the poles 7 in the direction X. Areas 11 are located between poles 7, which are free of metal 9 due to the shadow cast by the poles. Note that these areas 11 are arranged adjacently to each other in direction Y, perpendicular to direction X.

FIG. 7 shows the first cross-sectional view of the crossbar resist mask after a second deposition step. During a second deposition step (in vacuum), a memory material 13 is deposited at a substantially perpendicular angle on the surface of the substrate to form an electrically controllable memory layer 14. As appreciated by persons skilled in the art, the memory material comprises one or more material layers that together constitute the electrically controllable memory layer. The memory layer can for instance comprise a layer of an organic material such as Rotaxane, or an inorganic phase-change material.

The deposition of the memory material 13 may be preceded by deposition of a second adhesion layer (for example Ti, not shown) on the surface of the first deposited metal layer, to enhance adhesion of the memory material layer to the first deposited metal layer.

The memory layer 14 is deposited uniformly across the substrate due to the perpendicular angle of incidence. A small shadow area may possibly exist below the metal layer portion 9 on the sides of the poles 7.

The thickness of the memory layer 14 depends on the material being deposited, its properties as information storage material and on the total thickness of the crossbar circuit as designed. For an organic material the thickness may vary from about one monolayer to a few nanometers. For an inorganic material such as a phase change layer, the thickness may be about 1-2 nm, but this may depend on the actual phase change material.

It should be understood that the memory material 13 may also have suitable non-linear electrical properties in such a way that the crossbar circuit may function as (part of) a logic circuit.

FIG. 8 shows the second cross-sectional view of the crossbar resist mask after a third deposition step. The cross-sectional view extends in direction Y along line V-V of FIG. 2.

In a vacuum, a second deposition source E2 produces a vapour of a second metal 15 (or other conductive material). The metal vapour is directed towards the substrate 1 at a suitable angle (as shown by arrow 15) with the normal to the imprinted substrate 1, and otherwise in or along the direction Y of one of the wire sets to be formed in the 2-D grid.

Assuming line-of-sight shadowing, the deposition angle to the normal direction of the imprinted substrate depends on the aspect ratio of the height of resist layer and the width of the openings 12 in the grid mask 5. For example, at an aspect ratio between 0.5 and 2, the deposition angle is for instance between about 60 and about 45 degrees with respect to the normal direction. As will be appreciated by the person skilled in the art, a higher aspect ratio will allow a smaller deposition angle with respect to the normal direction.

The second metal 15 produced by source E2 is deposited on the surface of the substrate 1, if the poles 7 do not provide a shadow mask. In the direction Y the resist mask poles 7 (already covered partially by metal 9 and memory layer 14) are covered by a metal layer 16 on the top area and on their respective sides that face the second deposition source E2. Portions of the openings 12 in the crossbar resist mask M that are shadowed by the poles 7 remain free of metal.

The second metal 15 produced by source E2 reaches the bottom of the imprinted openings 12 only for lines that run in the selected deposition direction, which is parallel to direction Y, making upper conductive wires 17 (e.g., along line X-X), while the wires running in the perpendicular direction X are implicitly “cut” by the “shadow” of the raised resist poles 7.

It is noted that the metal flow 15 from the source E2 may be produced by evaporation, directional sputtering or by a molecular beam.

Again, to promote the deposition of the second metal 15 a relatively thin adhesion layer or seed layer (for example Ti) may be provided for, before depositing the second metal 15.

Moreover, the second source E2 may be identical to the first source E1, in which case the substrate 1 is rotated through 90° before deposition of the second metal 15 in the third deposition step. Note that a rotation angle other than 90° may be applicable with a non-orthogonal layout of the 2D wire grid.

Preferably, the deposition of the first metal 8 in the first deposition step, of the memory layer 14 in the second step and of the second metal 15 in the third step are carried out without breaking vacuum in a suitable deposition machine.

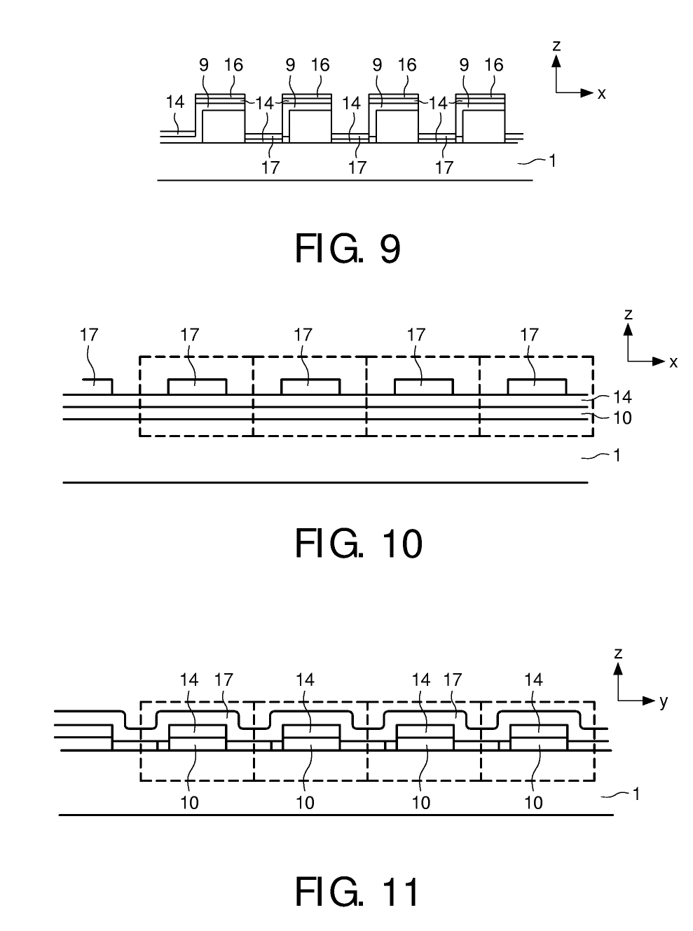

FIG. 9 shows the first cross-sectional view of the crossbar resist mask after the third deposition step. The cross-sectional view extends in direction X along line IV-IV of FIG. 2. Upper conductive wires 17 extending in the Y direction have been deposited on the substrate 1 between the poles 7.

FIG. 10 shows a cross-sectional view of the deposited structure after lift-off along a line X-X. Line X-X extending in the direction X. The memory layer 14, which is crossed by a plurality of upper conductive wires 17, is located on lower conductive wire 10. Each area where upper conductive wire 17 overlaps memory layer 14 and lower conductive wire 10 constitutes a memory cell of the crossbar circuit. Each memory cell is indicated by a dashed-line rectangle.

FIG. 11 shows a further cross-sectional view of the deposited structure after lift-off along line XI-XI. Line XI-XI extends in the direction Y. A plurality of lower conductive wires 10 is located on the substrate 1 (extending in the direction X perpendicular to the plane of the drawing). The memory layer 14 is located on each lower conductive wire 10. The plurality of lower wires 10 with covering memory layer 14 is crossed by an upper conductive wire 17. Each area where the upper conductive wire 17 overlaps a lower conductive wire 10 covered with a memory layer 14 constitutes a memory cell of the crossbar circuit. Each memory cell is indicated by a dashed-line rectangle.

It is noted that although not shown in the above cross-sectional views, both first and second conductive wires 10, 17 may have a somewhat asymmetrically shaped cross-section due to the directionality of the respective deposition process.

Advantageously, the method of the present invention does not require a planarisation step between the creation of the lower conductive wires 10 and the creation of the upper conductive wires 17 of the crossbar circuit device.

A physical or chemical state of the memory material 14 can be altered between at least two values under the influence of an electrical signal. Such states can be used for holding information as the value of the actual state can be detected in the crossbar circuit. It is noted that the electrically controllable state of the memory layer 14 may relate to various electrically controllable physical and/or chemical properties of the memory material. The memory layer 14 in a memory cell may act as an electrically programmable high-ohmic resistor, or it could make the equivalent of an (anti-)fuse or a field effect transistor with a programmable floating gate. The memory layer may also include material layers that provide a diode effect in order to reduce problems with leakage paths. The essence is here to have some memory effect that the electrically controllable state of the memory material manifests itself as an electrically observable change, even if it is for writing once only (OTP/ROM).

Further, it is noted that first and second metal 8, 15 may be identical conductive materials. Their choice may depend on many factors, which may relate to the desired crossbar circuit properties and to their respective electrical/physical/chemical properties. Also, their compatibility with (the processing of) micro-electronic devices may play a role since integration of a crossbar circuit device with a micro-electronic circuit or semiconductor device is desirable.

In the method described above, a lift-off process is used to remove the poles 7 of the crossbar resist mask M after deposition of the first and second metals 8, 15. Typically, lift-off is carried out by exposing the substrate comprising a resist pattern to a suitable solvent (e.g., acetone) under application of ultrasonic waves. It is considered that potentially removal of resist in the area of the crossbar circuit device may not be without difficulty.

Note that adjacent to the resist mask for the creation of the crossbar circuit, an additional peripheral portion of the resist pattern must have been defined for the creation of a peripheral circuit, which provides connection paths to other interconnect lines and/or electrical circuits (not shown) on the substrate. Typically, such other interconnect lines and/or electrical circuits on the substrate are created during earlier processing, for example using processing for micro-electronic devices.

During the first, second and third deposition step, material will be deposited on the additional peripheral portion of the resist pattern for forming interconnect lines between the crossbar circuit and the other electrical circuits mentioned above.

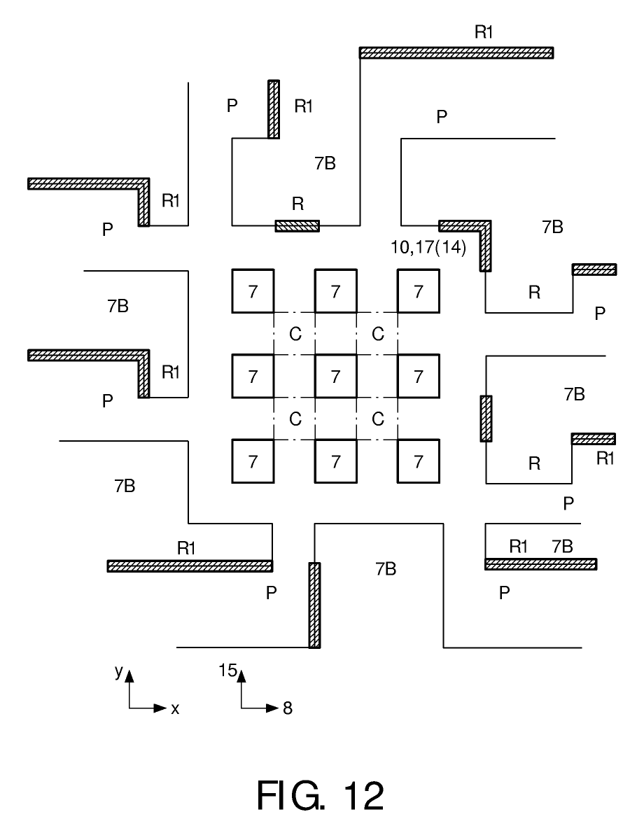

FIG. 12 shows a schematic layout of a crossbar circuit and part of a peripheral circuit before removal of the resist layer.

In the center the crossbar circuit is shown as an array of resist poles 7 (covered by first metal 9, memory material 14 and second metal 16). The metal in the two-dimensional grid of the crossbar circuit is indicated by references 10, 17. Dashed-line squares C depict the memory cells between the resist poles 7. Surrounding the array is a plurality of interconnecting lines P, which connects to further electrical circuits (not shown) on the substrate. Outer resist areas 7b are located between the interconnect lines P. Note that the outer resist areas 7b have become covered by first metal, memory material and second metal during the first, second and third deposition steps, respectively. Arrows 8 and 15 indicate the deposition direction of the first deposited metal 8 and the second deposited metal 15, respectively.

In particular, in some regions, metal that covers the outer resist areas 7b over relatively long distances, may contact the metal 10, 17 in the 2-D grid of the crossbar circuit over the side (s) which were exposed during the directional deposition of the first and second metals 8, 15. These contacting regions may hinder removal of the resist areas 7B and resist poles 7 of the crossbar resist mask.

A relatively long distance in this respect may relate to a length exceeding at least one width of an individual resist pole 7, but this may depend on the actual size of the crossbar circuit, its wires and the aspect ratio as used. Further, this distance also depends on the (ultrasonic) energy needed for tearing/breaking the contact between material to be removed from and material needed to remain on the surface of the substrate.

Also, difficulties during lift-off may arise at locations on the outer rim (edges) of the crossbar circuit where the deposited material may contact the lower and upper conductive wires and cause a short circuit between the upper and lower conductive wires, i.e. due to damage brought about by tearing of the deposited material(s) during the lift-off process.

In FIG. 12 the short circuit regions R of the crossbar circuit where lift-off may be difficult are indicated by shading.

Similarly, regions R1 of the peripheral portions P in which lift-off may be difficult are shaded. The regions R1 of the peripheral portions do not adversely affect the electrical properties of the respective peripheral portion P since only a single metal wire (either a lower 10 or an upper conductive wire 17) is connected to crossbar circuit from the peripheral portion P, due to shadow mask grating at the outer rim of the crossbar circuit area.

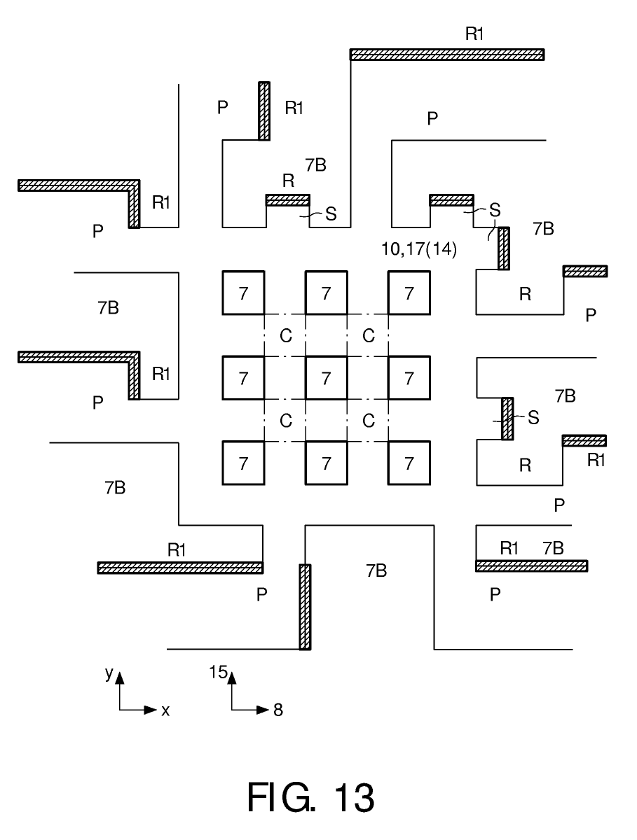

FIG. 13 shows a schematic layout of an adapted crossbar circuit and part of a peripheral circuit before removal of the resist layer.

In FIG. 13 entities with the same reference number refer to identical entities as shown in the preceding FIG. 12.

To eliminate areas R in the crossbar circuit portion of the resist pattern that are prone to possible failure of resist removal by lift-off, the method of the present invention in a further embodiment provides recesses (stubs) S into the resist areas 7B adjacent to the outer rim of the crossbar circuit portion of the resist pattern. Typically, the length and width of a stub S is substantially equal to the respective length and width of the resist poles 7. The distance between stubs S is fixed and is determined by the pattern of poles 7 in the wire grid. The stubs S are arranged in such a way that vertical edges of metal remaining after the lift-off process are not too close to an area where a second conductive wire overlap a first conductive wire to avoid electrical short circuit(s) between them.

Thus, when exposed to the directional metal flow 8, 15 during the first and third deposition step, the stub S effectively provides a shadow effect and divides the relatively wide regions R into smaller regions, which may be removed with lift-off without difficulty.

The regions R1 in the peripheral portions P may also be reduced by providing stubs into the sides, which are to be exposed to the directional deposition of metal 8, 15 during the first and third deposition step. Again, the stubs S are recesses, which invade the resist areas 7B adjacent to the peripheral portions P. Similarly as mentioned above, the stubs provide a shadow effect on the sides during the first or third deposition step. Thus, the large regions R1 are divided in smaller regions, which may be removed by lift-off with less effort than larger undivided regions R1.

Furthermore, the lift-off process may be enhanced by applying a brittle conductive material, for example chromium, as first and/or second metal 8, 15. Such brittle materials are known to be prone to (spontaneous) cracking, in particular at sharp transitions (of height) in a device or resist structure.

It is noted that the first deposited metal 8 may also be a brittle metal, since the first directional deposition step may cause some resist sides to become (partially) covered by metal. In that case, the spontaneous cracking of the brittle metal may help to avoid electrical short circuits that may originate from this side coverage.

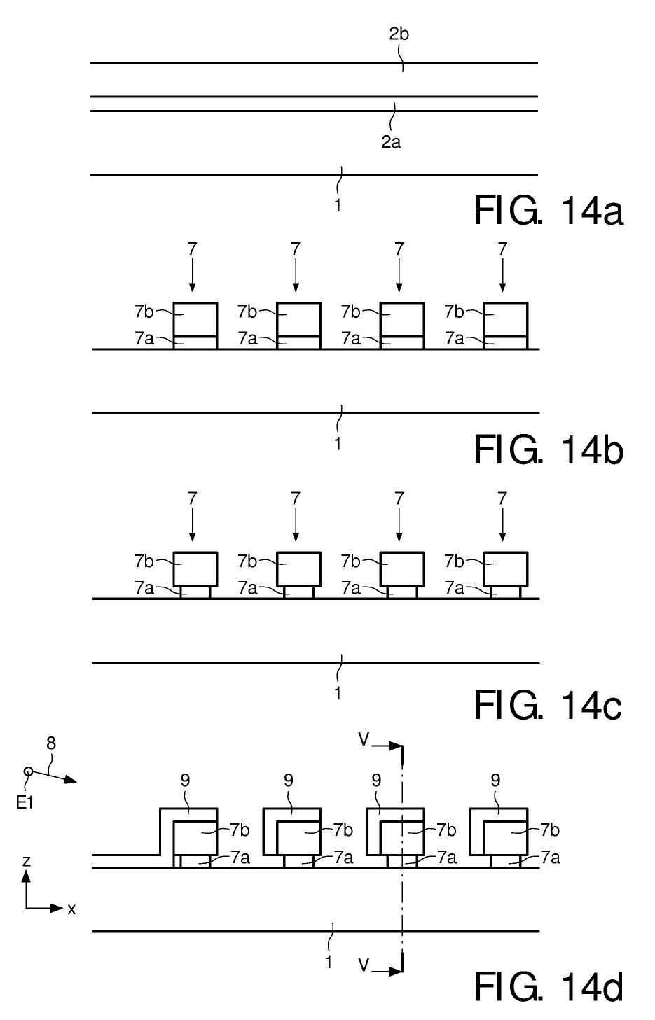

FIG. 14a-14d illustrate the formation of a crossbar resist mask according to a further embodiment of the present invention. In FIGS. 14a-14d, entities with the same reference number refer to identical entities as shown in the preceding figures.

The lift-off process can be enhanced by providing an under-etch of the resist layer. In that case the resist layer 2 consists of a first thin layer 2A and a second additional resist layer 2B, in which the first thin layer 2A is deposited on the substrate 1, and the second additional resist layer 2B is deposited on top of the first thin layer 2A.

The first thin layer 2A may be either a suitable thin metal film (e.g. Copper) or a first thin resist film.

In the case of a first thin resist film 2A, after the nano-imprinting step as discussed with reference to FIGS. 1b-1d, the resist poles 7 comprise a thin lower portion 7A and an upper portion 7B (FIG. 14b). Next, as shown in FIG. 14c, the thin lower portion 7A is partially etched away in a direction parallel to the surface of the substrate 1. FIG. 14d shows the first deposition step on the under-etched resist poles 7.

In the case of a thin metal film 2A, under-etching may be carried out directly after the imprinting step, in which case the portion of the metal thin film exposed to the etching process is removed before, in a subsequent step, the first directional deposition step is carried out.

It is noted that in the description of the present invention as given above, the crossbar circuit comprises a orthogonal 2D grid layout, as disclosed in the prior art. However, it is conceivable that a crossbar circuit may have a different grid layout, for example the 2D grid may be hexagonal, triangular, or rhomboid. In these cases, the angle between deposition directions X and Y will differ from the perpendicular angle as shown in the Figures, and, instead, will correspond to the angle between the directions of the first and second conductive wires 10, 17 as defined by the 2D grid layout.

Also, more than two non-orthogonal deposition directions may be applied depending on the actual grid layout. For example, a grid may have a triangular layout, in which case three deposition directions exist. In this case, directional deposition of materials will occur in more than two directions.

It is noted that although the method according to the present invention is described in relation to a crossbar circuit with features in the range of nanometers, the method may also be applicable to crossbar circuits with features in the range of micrometers. In that case under the given aspect ratio (0.5-2), the thickness of the imprintable layer may be in the range of a few to a few tens of micrometers. Sizes of the poles and openings scale accordingly. Such circuits with micrometer scale features may comprise, for example, a matrix of optical emitters, or a pixel-memory matrix.

Also, it is noted that the method of the present invention may be applied to materials other than the first and second conductive materials, i.e. to use directional deposition of such further materials within the crossbar circuit. Such further materials may comprise conductor, semi-conductor or insulator materials. It is conceivable that depending on the desired functionality of a crossbar circuit, the crossbar circuit may comprise such further materials next to, or instead of, the first and second conductive materials. It is even conceivable that the method of the present invention is used in a situation where both first and second materials are not conductors.

1. Method for manufacturing a crossbar circuit device on a substrate, the crossbar circuit device comprising a first grid of first wires and a second grid of second wires, the first wires extending in a first direction, the second wires extending in a second direction, the first direction of the first wires and the second direction of the second wires being arranged relative to each other to form a two-dimensional wire grid, each first wire being separated from each second wire by an intermediate layer located at a location where the first wire and the second wire, overlap;
the method comprising a step of depositing an imprintable layer on the substrate,
characterized by
imprinting a two-dimensional grid mask into the imprintable layer by a mould, the grid mask comprising a plurality of poles and openings interposed between adjacent poles and said grid mask being complementary to the two-dimensional wire grid;
directionally depositing a first material in substantially the first direction on the two-dimensional grid mask; and
directionally depositing a second material substantially the second direction on the two-dimensional grid mask,
the two-dimensional grid mask acting as a shadow mask during the directional deposition of the first and second material.

2. Method for manufacturing a crossbar circuit device according to claim 1, further comprising:
depositing an intermediate layer material to form the intermediate layer after the directional deposition of the first material and before the directional deposition of the second material.

3. Method for manufacturing a crossbar circuit device according to claim 1, further comprising:
after imprinting the two-dimensional mask, removing a residual layer from recessed areas of the 2-D grid mask.

4. Method for manufacturing a crossbar circuit device according to claim 1, wherein the directional deposition of the first or second material is carried out at a deposition angle with the normal direction of the imprinted substrate, the deposition angle depending on an aspect ratio of the grid mask, the aspect ratio being defined as the ratio of the height of pole over the width of the opening between adjacent poles.

5. Method for manufacturing a crossbar circuit device according to claim 4, wherein the aspect ratio is between 0.5 and 2, and the deposition angle is about 60 to about 45 degrees with respect to a normal direction on the substrate.

6. Method for manufacturing a crossbar circuit device according to claim 1, wherein the directional deposition of the first material or the second material comprises at least one of the following:
directionally evaporating the material,
directionally sputtering the material and
using a molecular beam comprising the material.

7. Method for manufacturing a crossbar circuit device according to claim 1, wherein the first direction and the second direction are orthogonal.

8. Method for manufacturing a crossbar circuit device according to claim 1, wherein the first direction and the second direction are non-orthogonal.

9. Method for manufacturing a crossbar circuit device according to claim 8, wherein the method further comprises:
directionally depositing a further material in substantially a further direction on the two-dimensional grid mask, the further direction being non orthogonal to the first direction and/or the second direction.

10. Method for manufacturing a crossbar circuit device according to claim 1, wherein the deposition of the intermediate layer material to form the intermediate layer is preceded by a deposition of an adhesion layer.

11. Method for manufacturing a crossbar circuit device according to claim 7, wherein the adhesion layer contains titanium.

12. Method for manufacturing a crossbar circuit device according to claim 1, wherein the height of the first wires or the second wires is equal to or less than half of the thickness of the imprintable layer.

13. Method for manufacturing a crossbar circuit device according to claim 1, wherein at least one of the first material and the second material is a conductive material.

14. Method for manufacturing a crossbar circuit device according to claim 1, wherein the intermediate layer contains a memory material.

15. Method for manufacturing a crossbar circuit device according to claim 14, wherein the physical and/or chemical properties of the memory material allow at least two electrically controllable states of the intermediate layer.

16. Method for manufacturing a crossbar circuit device according to claim 1, wherein the two-dimensional grid mask comprises outer rim stubs for dividing a side region at the outer rim into smaller regions.

17. Method for manufacturing a crossbar circuit device according to claim 1, wherein the two-dimensional grid mask comprises a peripheral portion pattern, in which peripheral portion pattern stubs are arranged in a peripheral side region for dividing the peripheral sidewall region into smaller regions.

18. Method for manufacturing a crossbar circuit device according to claim 1, wherein at least one of the first and second materials is a brittle material such as chromium.

19. Method for manufacturing a crossbar circuit device according to claim 1, wherein the imprintable layer consists of a first thin layer and a second additional resist layer; the first thin layer being deposited on the substrate, and the second additional resist layer being deposited on top of the first thin layer, and wherein imprinting the two-dimensional grid mask into the imprintable layer is followed by under-etching of the grid mask.

20. Method for manufacturing a crossbar circuit device according to claim 19, wherein the thin layer is either a thin resist film or a thin metal film.

21. Crossbar circuit device comprising a first grid of first wires and a second grid of second wires, the first wires extending in a first direction, the second wires extending in a second direction, the first direction of the first wires and the second direction of the second wires being arranged relative to each other to form a two-dimensional wire grid, each first wire being separated from each second wire by an intermediate layer located at a location where the first wire and the second wire overlap;
the crossbar circuit device being manufactured in accordance with claim 1.

22. Mould for use in the method according to claim 1, the mould comprising on its surface a geometrical shape for imprinting, characterized in that the geometrical shape comprises a two-dimensional grid mask.

23. Method for manufacturing a semiconductor device comprising the method for manufacturing of a crossbar circuit device in accordance with claim 1.

24. Semiconductor device comprising a crossbar circuit device according to claim 21.
